(19) United States
(12) Patent Application Publication
(10) Pub. No.: US 2025/0208459 A1
(43) Pub. Date: Jun. 26, 2025

(54) DISPLAY DEVICE

(71) Applicant: Japan Display Inc., Tokyo (JP)

(72) Inventors: Shinichiro OKA, Tokyo (JP); Yasushi TOMIOKA, Tokyo (JP)

(73) Assignee: Japan Display Inc., Tokyo (JP)

(21) Appl. No.: 18/985,116

(22) Filed: Dec. 18, 2024

(30) Foreign Application Priority Data
Dec. 21, 2023 (JP) 2023-215594

(51) Int. Cl. G02F 1/1335; H10H 29/855

(52) U.S. Cl. CPC G02F 1/133502; G02F 1/133528; G02F 1/133562; H10H 29/855; G02F 2202/28

(57) ABSTRACT

According to one embodiment, a display device comprises a display panel including a display area displaying an image, a cover member including an inner surface facing the display panel, and a resin layer formed on the inner surface and overlapping the display area. The resin layer includes a first area and a second area adjacent to the first area and having a refractive index different from a refractive index of the first area.

### CROSS-REFERENCE TO RELATED APPLICATIONS

This application is based upon and claims the benefit of priority from Japanese Patent Application No. 2023-215594, filed Dec. 21, 2023, the entire contents of which are incorporated herein by reference.

### FIELD

Embodiments described herein relate generally to a display device.

### BACKGROUND

Recently, various types of display devices have been proposed. For example, a display device in which patterns are printed in a display area in a transmissive ink to improve aesthetic of design is known. The reflectivity of a portion on which a pattern is formed is greater than those of portions on which no patterns are formed. Therefore, the pattern is emphasized when the display panel is in an off state. Thus, the pattern is visually recognizable.

However, steps are formed due to presence or absence of the ink. When the display panel is in an on state, light is scattered on corner portions of the ink and thus the pattern becomes visually recognizable with overlapping a displayed image. Thus, display quality may degrade.

### BRIEF DESCRIPTION OF THE DRAWINGS

FIG. 1 is a schematic plan view of a display device of the first embodiment.

FIG. 2 is a schematic cross-sectional view of the display device of the first embodiment.

FIG. 3 is a diagram showing a display device in which an illumination device and a display panel are in an off state or an on state.

FIG. 4 is a schematic diagram for explaining an example of a method of forming a first area and a second area.

FIG. 5 is a schematic cross-sectional view of a display device of the second embodiment.

FIG. 6 is a schematic plan view of a display device of the third embodiment.

FIG. 7 is a schematic cross-sectional view of the display device of the third embodiment.

FIG. 8 is a schematic cross-sectional view of a display device of the fourth embodiment.

### DETAILED DESCRIPTION

In general, according to one embodiment, a display device comprises: a display panel having a display area displaying an image; a cover member having an inner surface facing the display panel; and a resin layer formed on the inner surface and overlapping the display area. The resin layer includes a first area and a second area adjacent to the first area and having a refractive index different from a refractive index of the first area.

According to another embodiment, a display device comprises: a display panel having a display area displaying an image; a cover member having an inner surface facing the display panel; and a resin layer formed on the inner surface and overlapping the display area. The resin layer includes a first area and a second area adjacent to the first area and having a refractive index different from a refractive index of the first area. The resin layer is formed of a material whose refractive index varies according to ultraviolet rays.

The embodiments can provide a display device which can prevent the degradation in aesthetic of design.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. A plan view is defined as appearance when various types of elements are viewed parallel to the third direction Z.

### First Embodiment

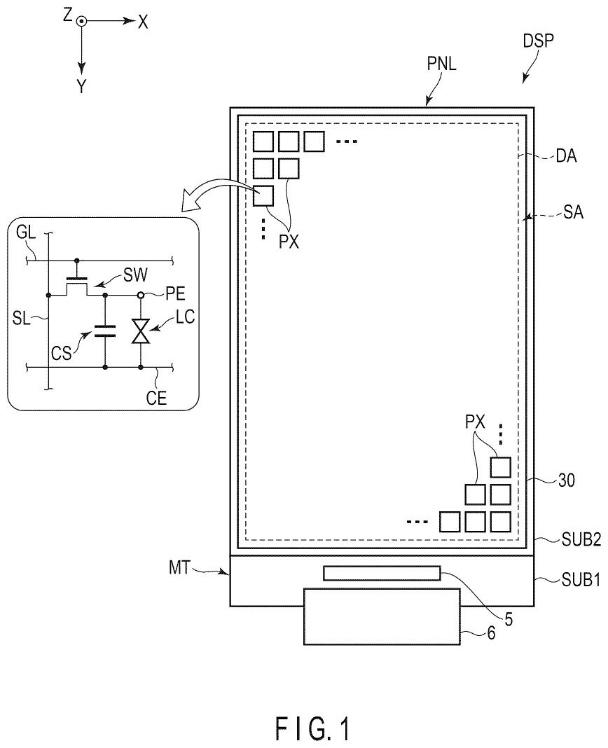

FIG. 1 is a schematic plan view of a display device DSP of the first embodiment. In the first embodiment, the display device DSP is a liquid crystal display device. The display device DSP comprises a display panel PNL, an IC chip 5, a wiring board 6, and a resin layer 30. The display device DSP comprises an illumination device to be described later, the illumination device illuminating the display panel PNL.

The display panel PNL comprises a first substrate SUB1 and a second substrate SUB2. The first substrate SUB1 faces the second substrate SUB2 in the third direction Z. The first substrate SUB1 and the second substrate SUB2 are formed in a flat plate shape parallel to the X-Y plane. In FIG. 1, each of the first substrate SUB1 and the second substrate SUB2 has a rectangular shape having long sides parallel to the second direction Y in plan view. The shapes of the first substrate SUB1 and the second substrate SUB2 are not limited to this example. For example, the shapes may be other shapes such as a rectangular shape having long sides parallel to the first direction X, a square shape, a circular shape, and an elliptical shape.

The display panel PNL includes a display area DA and a surrounding area SA. The display area DA is an area for displaying an image. The display area DA comprises a plurality of pixels PX arranged in a matrix in the first direction X and the second direction Y. The surrounding area SA surrounds the display area DA. The surrounding area SA includes a mounting portion MT. Of the first substrate SUB1, the mounting portion MT is a portion not overlapping the second substrate SUB2.

As shown in enlarged manner in FIG. 1, each of the plurality of pixels PX comprises a switching element SW, a pixel electrode PE, a common electrode CE, a liquid crystal layer LC, and the like. The switching element SW is constituted by, for example, a thin-film transistor (TFT) and is electrically connected to a scanning line GL and a signal line SL. The scanning line GL is electrically connected to the switching element SW in each of the pixels PX arranged in the first direction X. The signal line SL is electrically connected to the switching element SW in each of the pixels PX arranged in the second direction Y. The pixel electrode PE is electrically connected to the switching element SW. Each pixel electrode PE faces the common electrode CE, and drives the liquid crystal layer LC by an electric field produced between the pixel electrode PE and the common electrode CE. A capacitor CS is formed, for example, between for example, the common electrode CE and an electrode having the same electric potential as the common electrode CE and between the pixel electrode PE and an electrode having the same potential as the pixel electrode PE.

As an example, the scanning line GL, the signal line SL, the switching element SW, the pixel electrode PE, and the common electrode CE are provided on the first substrate SUB1. The pixel electrode PE may be provided on the first substrate SUB1. The common electrode CE may be provided on the second substrate SUB2.

In the shown example, the IC chip 5 and the wiring board 6 are mounted on the mounting portion MT. The IC chip 5 incorporates, for example, a display driver which outputs a signal necessary for displaying images. The wiring board 6 is a flexible printed circuit which can be bent. The IC chip 5 may be mounted on the wiring board 6.

The resin layer 30 overlaps the display area DA. In the shown example, the edge of the resin layer 30 is located between the display area DA and an end portion of the second substrate SUB2. The resin layer 30 may cover the entire surface of the second substrate SUB2 or the display area DA alone. Details of the resin layer 30 will be described later.

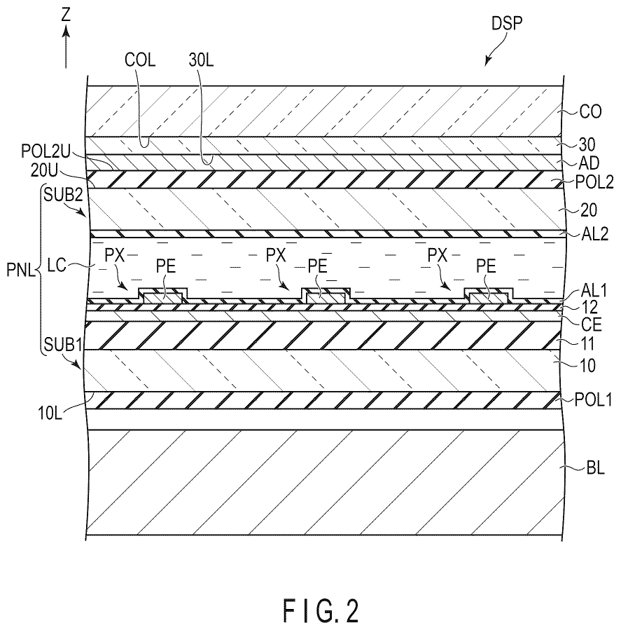

FIG. 2 is a schematic cross-sectional view of the display device DSP of the first embodiment.

The display panel PNL comprises the first substrate SUB1, the second substrate SUB2, and the liquid crystal layer LC.

The first substrate SUB1 comprises a transparent substrate 10, insulating layers 11 and 12, the common electrode CE, the plurality of pixel electrodes PE, and a first alignment film AL1. The first substrate SUB1 is provided above an illumination device BL. The insulating layer 11 is provided on the transparent substrate 10. The common electrode CE is provided over a plurality of pixels PX on the insulating layer 11. The insulating layer 12 is provided on the common electrode CE. The plurality of pixel electrodes PE are provided for the respective pixels PX on the insulating layer 12. The first alignment film AL1 covers the plurality of pixel electrodes PE and the insulating layer 12. The common electrode CE may be provided above the plurality of pixel electrodes PE. The scanning lines GL, the signal lines SL, and the switching elements SW shown in FIG. 1 are provided between the transparent substrate 10 and the common electrode CE.

The second substrate SUB2 comprises a transparent substrate 20 and a second alignment film AL2. The second substrate SUB2 is provided above the first substrate SUB1. The second alignment film AL2 is provided below the transparent substrate 20. Though not illustrated, a light-shielding layer, a color filter layer, an overcoat layer, and the like may be further provided on the second substrate SUB2. The color filter layer may be provided on the first substrate SUB1.

The liquid crystal layer LC is provided between the first substrate SUB1 and the second substrate SUB2. In the example of FIG. 2, the liquid crystal layer LC is provided between the first alignment film AL1 and the second alignment film AL2.

The transparent substrates 10 and 20 are insulating substrates formed of glass, plastic, and the like.

The insulating layer 11 is formed of a transparent insulating material. For example, the insulating layer 11 includes an inorganic insulating layer and an organic insulating layer.

The insulating layer 12 is formed of, for example, a transparent inorganic insulating material such as silicon nitride (SiNx).

The common electrode CE and the pixel electrode PE may be formed of, for example, a transparent conductive material such as indium tin oxide (ITO) or indium zinc oxide (IZO).

Each of the first alignment film AL1 and the second alignment film AL2 is a horizontal alignment film having an alignment restriction force along the X-Y plane. Each of the first alignment film AL1 and the second alignment film AL2 is an optical alignment film to which the alignment restriction force is imparted by ultraviolet irradiation. Each of the first alignment film AL1 and the second alignment film AL2 may be an alignment film subjected to rubbing treatment.

The display device DSP further comprises a first polarizer POL1, a second polarizer POL2, an adhesive layer AD, and a cover member CO.

The first polarizer POL1 is provided between the first substrate SUB1 and the illumination device BL. In the example shown in FIG. 2, the first polarizer POL1 adheres to the lower surface of the first substrate SUB1. More specifically, the first polarizer POL1 adheres to a lower surface 10L of the transparent substrate 10. The second polarizer POL2 is provided between the second substrate SUB2 and the resin layer 30. In the example of FIG. 2, the second polarizer POL2 adheres to the upper surface of the second substrate SUB2. More specifically, the second polarizer POL2 adheres to an upper surface 200 of the transparent substrate 20. Polarization axes of the first polarizer POL1 and second polarizer POL2 intersect each other on, for example, the X-Y plane.

The resin layer 30 is located on a side opposite to the liquid crystal layer LC with the second substrate SUB2 interposed therebetween. The adhesive layer AD bonds the lower surface 30L of the resin layer 30 and an upper surface POL2U of the second polarizer POL2 together. For example, the adhesive layer AD is formed of a transparent material such as an optical clear adhesive (OCA) and an optical clearer resin (OCR). The refractive index of the adhesive layer AD is about 1.4 to 1.55 but is not limited to this example.

The resin layer 30 is formed of a material whose refractive index varies according to ultraviolet irradiation. The resin layer 30 may be formed of a material whose refractive index increases by ultraviolet irradiation or a material whose refractive index decreases by ultraviolet irradiation.

As an example, the resin layer 30 is formed of an aromatic polyurethane. The aromatic polyurethane is synthesized by for example, polyaddition reaction of aromatic diisocyanate and a bifunctional alcohol. For example, as aromatic diisocyanates, for example, 4,4′-methylenediphenyl diisocyanate (MDI) and tolylene-2, 4′-diisocyanate (TDI) can be used. For example, as a bifunctional alcohol, 1, 4-bis(hydroxymethyl)benzene (HMB), 2-methyl-1, 3-propanediol (MPDO), and 1, 3-propanediol (PDO) can be used. Aromatic polyurethane is an example of a material whose refractive index increases by ultraviolet irradiation. The refractive index of aromatic polyurethane is around 1.58 to 1.65. This refractive index of the aromatic polyurethane includes both of the refractive index before the ultraviolet irradiation and the refractive index of after the ultraviolet irradiation.

The cover member CO is provided above the display panel PNL. The cover member CO includes an inner surface COL facing the display panel PNL in the third direction Z. The resin layer 30 is formed on the inner surface COL.

The cover member CO is formed of a transparent material such as glass and plastic. As an example, the cover member CO is formed of alkali aluminum silicate glass. The cover member CO may be formed, for example, in a film shape. The cover member CO may have a function of shielding ultraviolet rays contained in external light. In that case, the cover member CO can suppress variation in the refractive index of the resin layer 30 due to ultraviolet rays contained in external light. The refractive index of the cover member CO is around 1.5.

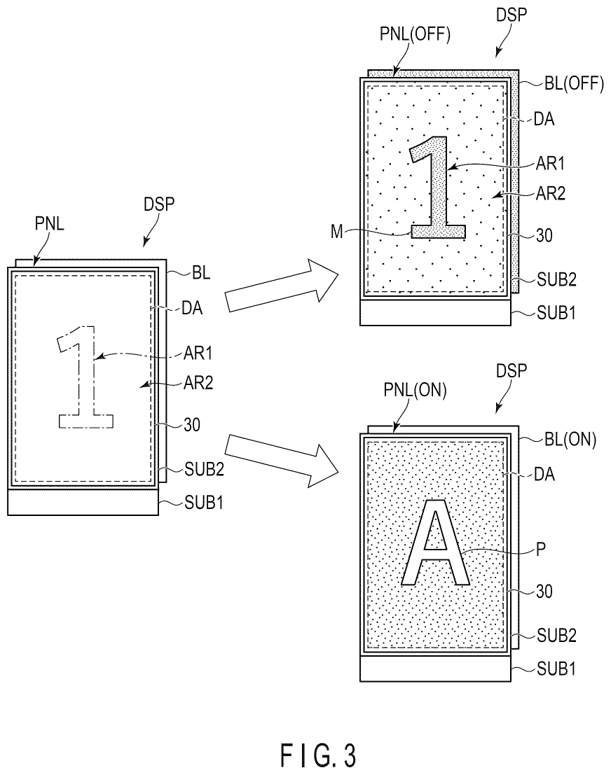

FIG. 3 is a diagram showing the display device DSP in which the illumination device BL and the display panel PNL are in the off state or the on state. The left-side diagram in FIG. 3 shows a configuration of the display device DSP. The upper-right diagram in FIG. 3 shows the illumination device BL and the display panel PNL that are in the off state. The lower-right diagram in FIG. 3 shows the illumination device BL and the display panel PNL that are in the on state.

The off state of the illumination device BL corresponds to a state where all of light sources included in the illumination device BL are turned off. The on state of the illumination device BL corresponds to a state where at least one of the light sources included in the illumination device BL is turned on.

The off state of the display panel PNL corresponds to a state where no electric field is formed in the liquid crystal layer LC shown in FIG. 2 during the illumination device BL being in the off state. Therefore, no image is displayed in the display area DA during each of the display panel PNL and the illumination device BL being in the off state.

The on state of the display panel PNL corresponds to a state where an electric field is formed in the liquid crystal layer LC during the illumination device BL being in the on state. Therefore, an image can be displayed in the display area DA during each of the display panel PNL and the illumination device BL being in the on state.

As shown in the left side of FIG. 3, the resin layer 30 is transparent and includes a first area AR1 and a second area AR2 adjacent to the first area AR1 and having a refractive index different from a refractive index of the first area AR1. The first area AR1 and the second area AR2 have the same thickness. Therefore, no step is formed between the boundary between the first area AR1 and the second area AR2. In other words, the surface of the resin layer 30 is even. The first area A1 and the second area A2 overlap the display area DA. For example, the first area AR1 is an area displaying letters, figures, and the like. The second area AR2 surrounds the first area AR1. In the example of FIG. 3, the area of the first area AR1 is smaller than the area of the second area AR2. Further, the refractive index of the first area AR1 is higher than the refractive index of the second area AR2.

The refractive index of the second area AR2 may be higher than the refractive index of the first area AR1. Further, the resin layer 30 may include more than three areas having refractive indexes different from one another.

As shown in the upper-right of FIG. 3, during the illumination device BL and the display panel PNL being in the off state, when the external light is made incident on the display device DSP, the external light is refracted in the first area AR1 and the second area AR2. The refractive indexes of the first area AR1 and the second area AR2 are different from each other. Therefore, the light refracted on the first area AR1 and the light refracted on the second area AR2 travel in directions different from each other. In this manner, the differences in travel directions between the light passing through the first area AR1 and the light passing through the second area AR2 allow a user to visually recognize the first area AR1 as a pattern M. In order to make the pattern M visually recognizable, the refractive index difference between the first area AR1 and the second area AR2 needs to be 0.003 or more. In the present embodiment, the refractive index difference is 0.03 to 0.04. The pattern M is made due to the refractive index difference between the first area AR1 and the second area AR2. Thus, in terms of improving visibility of the pattern M, a greater refractive index difference is preferable.

As shown in the lower-right of FIG. 3, during the illumination device BL and the display panel PNL being in the on state, the display panel PNL is illuminated with the light from the illumination device BL and thus an image P is displayed in the display area DA. The resin layer 30 is transparent. Thus, display light forming the image P passes through the resin layer 30. This configuration allows a user to visually recognize the image P. At this time, if the refractive index difference between the first area AR1 and the second area AR2 is great, display light is refracted in different directions in the respective first area AR1 and second area AR2. This may make the image P visually recognizable with overlapping the pattern M. Therefore, in terms of suppressing the decrease in the visibility of the image P, the refractive index difference between the first area AR1 and the second area AR2 is preferably less than or equal to 0.1.

Next, a method of forming the first area AR1 and the second area AR2 will be described.

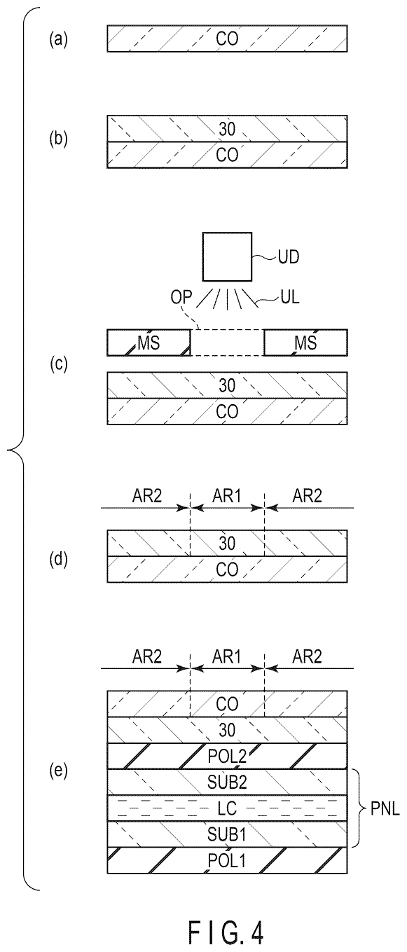

FIG. 4 is a schematic diagram for explaining an example of the method of forming the first area AR1 and the second area AR2.

First, as shown in FIG. 4 (a), the cover member CO is prepared.

Next, as show in FIG. 4 (b), a material for forming the resin layer 30 is applied to the cover member CO. Thereafter, the resin layer 30 is formed by drying this cover member CO to which the material is applied. For example, an ink-jet method or a spin coating is used as the method of applying the material. For example, aromatic polyurethane is used as the material.

Next, as shown in FIG. 4 (c), a mask MS is provided above the resin layer 30. The mask MS includes an aperture OP corresponding, for example, to the first area AR1 shown in FIG. 3. Thereafter, an ultraviolet irradiation device UD irradiates the resin layer 30 with an ultraviolet ray UL through the aperture OP of the mask MS. The refractive index of the area irradiated with the ultraviolet ray UL increases from the refractive index before the ultraviolet irradiation. In contrast, the refractive index of areas that are not irradiated with the ultraviolet ray UL do not substantially vary between before and after the ultraviolet irradiation. For example, in a case where aromatic polyurethane is used, the refractive index of the area irradiated with the ultraviolet ray UL increases by around 0.04 after the ultraviolet irradiation.

Thus, as shown in FIG. 4 (d), the first area AR1 irradiated with the ultraviolet ray UL (a high refractive index area) and the second area AR2 not irradiated with the ultraviolet ray UL (a low refractive index area) are formed.

Next, as shown in FIG. 4 (e), the first polarizer POL1 and the second polarizer POL2 are bonded to the display panel PNL in which the first substrate SUB1, the liquid crystal layer LC, and the second substrate SUB2 are stacked in this order. Then the cover member CO in which the resin layer 30 is formed, is bonded to the second polarizer POL2 by means of adhesive.

According to the present embodiment, the resin layer 30 overlapping the display area DA has the first area AR1 and the second area AR2 having refractive indexes different from each other. This difference in refractive index renders the first area AR1 or the second area AR2 visually recognizable as the pattern M. This can increase the aesthetic of design. In addition, the resin layer 30 is covered

with the cover member CO. The cover member CO can prevent the surface of the resin layer 30 from wearing and the like. Therefore, a degradation in the aesthetic of design due to deficits in the resin layer 30 can be suppressed.

The first area AR1 and the second area AR2 have the same thicknesses. Thus, no step is formed at the boundary between the first area AR1 and the second area AR2. Therefore, undesirable scattering of light can be suppressed. In particular, scattering of the external light during the illumination device BL and the display panel PNL being in the on state, and scattering of the display light can be suppressed. Therefore, degradation in display quality of an image displayed in the display area DA can be suppressed.

In the present embodiment, the resin layer 30 is in contact with the cover member CO and the adhesive layer AD. In this embodiment as well, the pattern M of the resin layer 30 is visually recognizable when at least one of a refractive index difference between the resin layer 30 and the cover member CO and a refractive index difference between the resin layer 30 and the adhesive layer AD is a certain refractive index difference.

For example, when the refractive index difference between the resin layer 30 and the cover member CO is the certain refractive index difference, light is refracted on the interface between the resin layer 30 and the cover member CO and thus the pattern M is visually recognizable. The refractive index of the resin layer 30 may be greater or less than the refractive index of the cover member CO.

For example, when the refractive index difference between the resin layer 30 and the adhesive layer AD is the certain refractive index difference, light is refracted on the interface between the resin layer 30 and the adhesive layer AD and thus the pattern M is visually recognizable. The refractive index of the resin layer 30 may be greater or less than the refractive index of the adhesive layer AD.

Even when both of the refractive index difference between the resin layer 30 and the cover member CO and the refractive index difference between the resin layer 30 and the adhesive layer AD are the certain refractive index difference, the resin layer 30 has an extremely thin thickness of around 1 μm. This thickness does not cause multiple reflections accounting for degradation in the visibility.

Based on the analysis by the inventor, the refractive index difference needs to be 0.1 or more and preferably is 0.2 or more in order to make the pattern M of the resin layer 30 visually recognizable.

The inventor has conducted a brief experiment to examine the visibility of the pattern M on the resin layer 30. The following is the contents of the experiment. First, a glass having the refractive index of 1.5 is adopted as the cover member CO, and the resin layer 30 is formed of aromatic polyurethane on the cover member CO. The refractive index of the resin layer 30 is around 1.58 to 1.65. The thickness of the resin layer 30 is 1 μm. Thereafter, a transparent liquid having the refractive index of 1.3 is adopted as the adhesive layer AD, and then the resin layer 30 and the second polarizer POL2 are bonded together. In this state, the pattern M of the resin layer 30 could be visually recognized from a side of the cover member CO.

### Second Embodiment

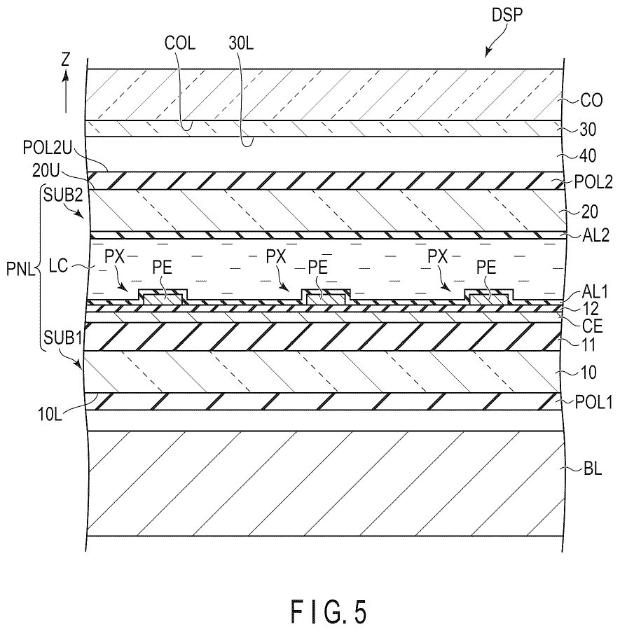

Next, the second embodiment will be described. FIG. 5 is a schematic cross-sectional view of a display device DSP of the second embodiment. The same elements as those of the first embodiment are denoted by the same reference numbers and overlapping descriptions of these elements are omitted.

In the display device DSP shown in FIG. 5, an air layer 40 is interposed between a resin layer 30 and a second polarizer POL2. A refractive index of the resin layer 30 is greater than a refractive index of the air layer 40. Thus, light is refracted on the interface (a lower surface 30L) between the resin layer 30 and the air layer 40. Thereafter, the pattern M is visually recognizable in the display device DSP shown in FIG. 5 as well. In addition, since the resin layer 30 is covered with a cover member CO, a degradation in the aesthetic of design due to the deficit in the resin layer 30 can be suppressed.

In addition to this effect, the display device DSP of the second embodiment exhibits the same effects as those exhibited by the display device DSP of the first embodiment.

### Third Embodiment

Next, the third embodiment will be described. The same elements as those of the embodiments are denoted by the same reference numbers and overlapping descriptions of these elements are omitted.

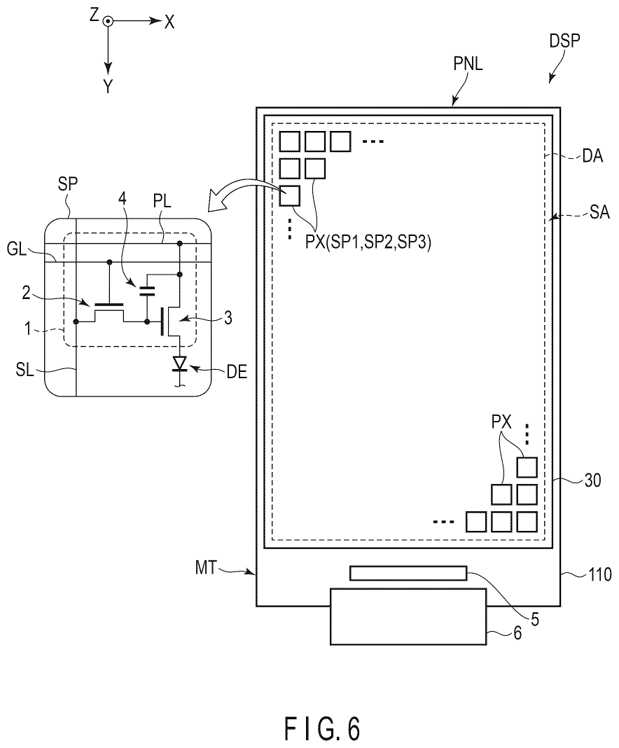

FIG. 6 is a schematic plan view of a display device DSP of the third embodiment. The display device DSP of the third embodiment is an organic electroluminescent display device comprising, for example, an organic light emitting diode (OLED) as display elements. The display device DSP comprises a display panel PNL. The display panel PNL comprises an insulating substrate 110. In FIG. 6, the insulating substrate 110 has a rectangular shape having long sides parallel to the second direction Y in plan view. The shape of the insulating substrate 110 is not limited to this example. For example, the shape may be other shape such as a rectangular shape having long sides parallel to the first direction X, a square shape, a circular shape, and an elliptical shape. The substrate 110 is formed of, for example, an insulating material such as glass or plastic.

The display area DA comprises a plurality of pixels PX arranged in a matrix in the first direction X and the second direction Y. Each pixel PX comprises a plurality of subpixels SP. As an example, the pixel PX includes a red subpixel SP1, a green subpixel SP2, and a blue subpixel SP3. In addition to the subpixels of the above three colors, the pixel PX may comprise four or more subpixels including a subpixel of another color such as white.

As shown in the enlarged manner in FIG. 6, the subpixel SP comprises a pixel circuit 1 and a display element DE driven by a pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

In the pixel switch 2, a gate electrode is connected to a scanning line GL. Either a source electrode or a drain electrode of the pixel switch 2 is connected to a signal line SL. The other is connected to a gate electrode of the drive transistor 3 and the capacitor 4. In the drive transistor 3, one of the source electrode and the drain electrode is connected to a power line PL and the capacitor 4. The other is connected to the anode of the display element DE. The configuration of the pixel circuit 1 is not limited to the example shown in the figure.

The display element DE is an organic light emitting diode (OLED) as a light emitting element. For example, the subpixel SP1 comprises a display element DE that emits light corresponding to a red wavelength, the subpixel SP2 comprises a display element that emits light corresponding to a green wavelength, and the subpixel SP3 comprises a display element that emits light corresponding to a blue wavelength. The display element DE is not limited to the organic light emitting diode and may be other light emitting elements such as the micro light emitting diode.

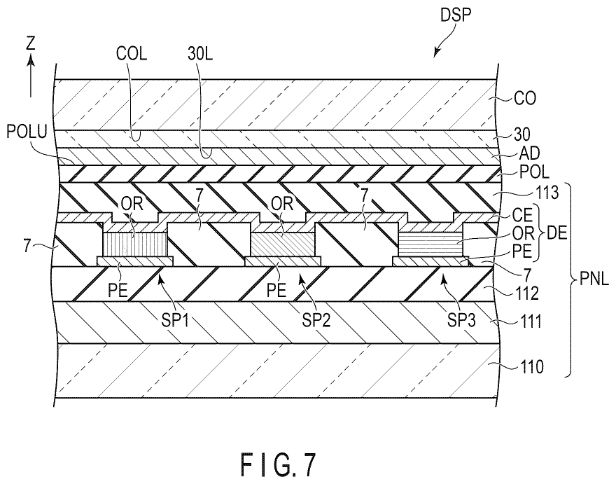

FIG. 7 is a schematic cross-sectional view showing the display device DSP of the third embodiment.

The display panel PNL comprises the insulating substrate 110, a circuit layer 111, insulating layers 112 and 113, a rib 7, and a plurality of display elements DE provided above the insulating substrate 110. The circuit layer 111 is provided on the insulating substrate 110. The circuit layer 111 is covered with the insulating layer 112.

The circuit layer 111 includes various circuits such as the pixel circuit 1 shown in FIG. 7 and various lines such as the scanning line GL, the signal line SL, and the power line PL. As an example, the insulating layer 112 includes an inorganic insulating layer and an organic insulating layer. The display element DE includes a pixel

electrode PE, an organic layer OR, and a common electrode CE. The pixel electrode PE is provided in each subpixel SP. The common electrode CE is provided to be shared with the common electrode CE and the plurality of display elements DE. The organic layer OR is provided between the pixel electrode PE and the common electrode CE.

The pixel electrode PE is provided on the insulating layer 112. A rib 7 is provided on the insulating layer 112 and the pixel electrode PE. A peripheral portion of the pixel electrode PE is covered with the rib 7. The organic layer OR is provided on the pixel electrode PE. The organic layer OR is surrounded by the rib 7. The common electrode CE covers the organic layer OR and the rib 7.

The organic layer OR includes a light emitting layer composed of an organic EL material. The organic layer OR may include functional layers such as a hole injection layer, a hole transport layer, an electron blocking layer, a hole blocking layer, an electron transport layer, and an electron injection layer.

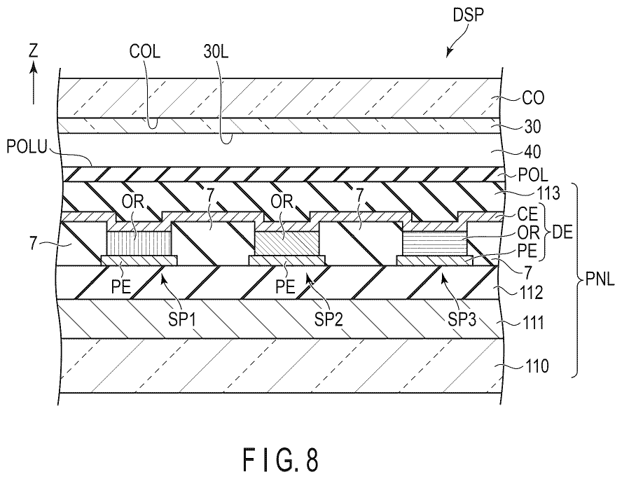

The insulating layer 113 covers the plurality of display elements DE. In FIG. 8, the insulating layer 113 covers the common electrode CE. The insulating layer 113 includes an organic layer which planarizes the uneven parts formed by the rib 7 and an inorganic layer (a sealing layer) protecting the organic layer OR from moisture and the like.

The display device DSP further comprises a polarizer POL provided above the insulating layer 113, an adhesive layer AD, and a cover member CO.

The polarizer POL is bonded to the upper surface of the insulating layer 113. The resin layer 30 faces the polarizer POL in the third direction Z. The adhesive layer AD bonds a lower surface 30L of the resin layer 30 and an upper surface POLU of the polarizer POL together.

In the display device shown in FIG. 7 as well, the resin layer 30 is covered with a cover member CO, and thus a degradation in the aesthetic of design due to the deficit in the resin layer 30 can be suppressed.

In addition to this effect, the display device DSP of the third embodiment exhibits the same effects as those exhibited by the display device DSP of the first embodiment.

### Fourth Embodiment

Next, the fourth embodiment will be described. FIG. 8 is a schematic cross-sectional view of a display device DSP of the fourth embodiment. The same elements as those of the embodiments are denoted by the same reference numbers and overlapping descriptions of these elements are omitted.

In the display device shown in FIG. 8, an air layer 40 is interposed between a resin layer 30 and a second polarizer POL2. The pattern M is visually recognizable in the present embodiment as well.

In addition, since the resin layer 30 is covered with a cover member CO, a degradation in the aesthetic of design due to the deficit in the resin layer 30 can be suppressed.

In addition to this effect, the display device DSP of the fourth embodiment exhibits the same effects as those exhibited by the display devices DSP of each of the embodiments.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a display panel having a display area displaying an image;
a cover member having an inner surface facing the display panel; and
a resin layer formed on the inner surface and overlapping the display area, wherein
the resin layer includes a first area and a second area adjacent to the first area and having a refractive index different from a refractive index of the first area.

2. The display device of claim 1, wherein
a difference between a refractive index of the resin layer and a refractive index of the cover member is 0.1 or more.

3. The display device of claim 1, wherein
a difference between the refractive index of the first area and the refractive index of the second area is 0.003 or more.

4. The display device of claim 1, wherein
the first area overlaps the display area.

5. The display device of claim 1, wherein
the resin layer is formed of an aromatic polyurethane.

6. The display device of claim 1, further comprising:
an illumination device illuminating the display panel;
a first polarizer and a second polarizer, wherein
the display panel comprises a first substrate, a second substrate facing the first substrate, and a liquid crystal layer provided between the first substrate and the second substrate,
the first polarizer is provided between the first substrate and the illumination device,
the second polarizer is provided between the second substrate and the resin layer, and
the resin layer faces the second polarizer.

7. The display device of claim 6, further comprising:
an adhesion layer bonding the resin layer and the second polarizer together.

8. The display device of claim 7, wherein
a difference between the refractive index of the resin layer and a refractive index of the adhesive layer is 0.1 or more.

9. The display device of claim 6, wherein
an air layer is interposed between the resin layer and the second polarizer.

10. The display device of claim 1, wherein
the display panel comprises an insulating substrate, a plurality of display elements facing the insulating substrate, and an insulating layer covering the plurality of display elements,
the display device further comprises a polarizer facing the insulating layer, and
the resin layer faces the polarizer.

11. The display device of claim 10, further comprising:
an adhesion layer bonding the resin layer and the polarizer together.

12. The display device of claim 11, wherein
a difference between the refractive index of the resin layer and a refractive index of an adhesive layer is 0.1 or more.

13. The display device of claim 10, wherein
an air layer is interposed between the resin layer and the polarizer.

14. The display device of claim 10, wherein
each of the plurality of display elements is a light emitting diode.

15. A display device, comprising:
a display panel having a display area displaying an image;
a cover member having an inner surface facing the display panel; and
a resin layer formed on the inner surface and overlapping the display area, wherein
the resin layer includes a first area and a second area adjacent to the first area and having a refractive index different from a refractive index of the first area and is formed of a material whose refractive index varies according to ultraviolet rays.

16. The display device of claim 15, wherein
the resin layer is made of a material whose refractive index increases according to ultraviolet rays.

17. The display device of claim 15, wherein
the resin layer is made of a material whose refractive index decreases according to ultraviolet rays.
